(19) United States
(12) Patent Application Publication
(10) Pub. No.: US 2008/0150594 A1
(43) Pub. Date: Jun. 26, 2008

(54) Start-up circuit for supply independent biasing

(76) Inventors: Stewart S. Taylor, Beaverton, OR (US); Jing-Hong C. Zhan, HsinChu (TW)

Correspondence Address: INTEL CORPORATION;c/o INTELLEVATE, LLC, P.O. BOX 52050, MINNEAPOLIS, MN, 55402, US

(21) Appl. No.: 11/644,592

(22) Filed: Dec. 22, 2006

(51) Int. Cl. H03K 17/22; H04N 5/38

(52) U.S. Cl. 327/143; 327/198; 455/127.1

(57) ABSTRACT

A wireless device includes a supply independent bias circuit such as a bandgap current generator or a Proportional-To-Absolute-Temperature (PTAT) current generator. A start-up circuit that includes an amplifier and a Schmidt trigger to provide the desired start-up that avoids regulation to an undesired state.

Technological developments permit digitization and compression of large amounts of voice, video, imaging, and data information. Evolving applications have greatly increased the transfer of large amounts of data from one device to another or across a network to another system. Computers have faster central processing units and substantially increased memory capabilities to handle this transfer of data. Currently, supply voltages for the central processing units, the Radio Frequency (RF) platforms used in transferring data across networks, and the circuitry embedded within these devices are being scaled down. This poses limitations on commonly used circuits such as traditional voltage references, as it is becoming increasingly difficult to keep transistors such as Metal Oxide Silicon Field Effect Transistors (MOSFETs) in their proper regions of operation. As the need for lower supply voltages and lower powered circuits increase, this lower supply voltage limitation becomes a more serious impediment. Therefore, improved circuits and a method for generating supplies for reference bias are needed.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a diagram that illustrates a wireless device that implements a start-up circuit for supply independent biasing in accordance with the present invention;

FIG. 2 is a circuit schematic that illustrates one embodiment for a supply-independent bias circuit with robust start-up; and

FIG. 3 is a circuit schematic that illustrates another embodiment for a supply-independent bias circuit with robust start-up.

It will be appreciated that for simplicity and clarity of illustration, elements illustrated in the figures have not necessarily been drawn to scale. For example, the dimensions of some of the elements may be exaggerated relative to other elements for clarity. Further, where considered appropriate, reference numerals have been repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

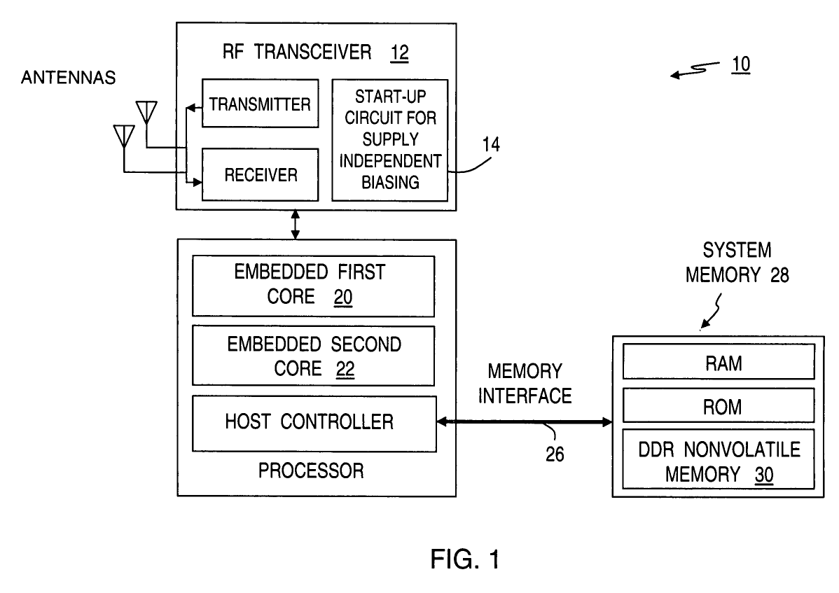

The embodiment illustrated in FIG. 1 shows a wireless communications device 10 that includes one or more radios to allow communication with other over-the-air communication devices. Communications device 10 may operate in wireless networks such as, for example, Wireless Fidelity (Wi-Fi) that provides the underlying technology of Wireless Local Area Network (WLAN) based on the IEEE 802.11 specifications, WiMax and Mobile WiMax based on IEEE 802.16-2005, Wideband Code Division Multiple Access (WCDMA), and Global System for Mobile Communications (GSM) networks, although the present invention is not limited to operate in only these networks. The radio subsystems collocated in the same platform of communications device 10 provide the capability of communicating in an RF/location space with the other devices in the network.

It should be noted that the present invention is not limited to wireless applications and may be used in a variety of products. For instance, the claimed subject matter may be incorporated into desktop computers, laptops, smart phones, MP3 players, cameras, communicators and Personal Digital Assistants (PDAs), medical or biotech equipment, automotive safety and protective equipment, automotive infotainment products, etc. However, it should be understood that the scope of the present invention is not limited to these examples.

The simplistic embodiment illustrates the coupling of antenna(s) to the transceiver 12 to accommodate modulation/demodulation. In general, analog front end transceiver 12 may be a stand-alone Radio Frequency (RF) discrete or integrated analog circuit, or transceiver 12 may be embedded with a processor as a mixed-mode integrated circuit where the processor processes functions that fetch instructions, generate decodes, find operands, and perform appropriate actions, then stores results. A supply independent bias circuit with a functional start-up block 14 may generate reference voltages and/or currents with little dependence to temperature. The processor may include baseband and applications processing functions and utilize one or more processor cores 20 and 22 to handle application functions and allow processing workloads to be shared across the cores. The processor may transfer data through an interface 26 to memory storage in a system memory 28.

Precision voltage reference circuits are important to the design of mixed-signal and analog integrated circuits such as, for example, oscillators, Phase Lock Loops (PLLs) and data converters. Applications such as a successive approximation Analog-to-Digital Converter (ADC) need a reference voltage generator to provide high-precision references. Thus, Analog, RF/wireless, digital, and mixed-signal design areas may need voltage references that are stable over process, power supply voltage, and temperature variations.

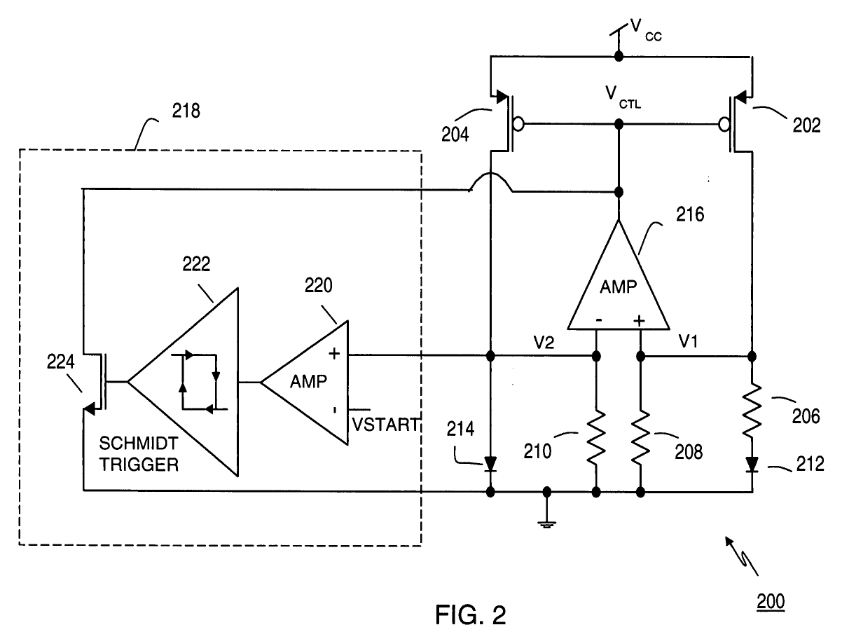

FIG. 2 shows a simplified supply independent bias circuit 200 with a functional start-up block in accordance with a first embodiment of the present invention. The illustrated embodiment includes a supply independent constant bias current circuit, e.g., a bandgap current generator, but the present invention is not limited to a bandgap generator and it should be noted that other bias circuits may be used. By way of example, another embodiment may include a Proportional-To-Absolute-Temperature (PTAT) current generator in supply independent bias circuit 200.

The low-voltage supply independent bias circuit shown in the figure includes P-channel transistors 202 and 204, resistors 206, 208 and 210, diodes 212 and 214 and Operational Amplifier (AMP) 216. AMP 216 generates the drive voltage of V_{CTL} to the commonly connected gates of transistors 202 and 204. The voltage V1 supplied to one input of AMP 216 is generated at the node that connects the drain terminal of transistor 202 with a parallel combination of resistor 208 and resistor 206 that is serially connected with diode 212. The voltage V2 supplied to the other input of AMP 216 is provided from the node that connects the drain terminal of transistor 204 with the parallel connected diode 214 and resistor 210. Thus, the proper sizing of transistors 202 and 204, resistors 206, 208 and 210 and diodes 212 and 214 generate the supply independent voltages V1 and V2. A supply independent constant current may be obtained by mirroring (copying) the currents conducted by transistors 202 and 204.

In accordance with the present invention, a start-up circuit 218 is included with supply independent bias circuit 200. The figure shows a simplified implementation of the start-up circuit 218 that includes an amplifier (AMP) 220, a Schmidt trigger 222 and an N-channel transistor 224. AMP 220 works with Schmidt trigger 222 to provide the desired start-up. For instance, when V2 is lower than a preset voltage V_{START} supplied to one input of AMP 220, Schmidt trigger 222 switches to set the gate voltage of transistor 224 to a high voltage value. The high gate voltage forces current to flow through transistor 224, lowering the gate voltage of transistors 202 and 204. The current conducted by transistor 204 increases the node voltage V2, and when the voltage V2 is greater than the voltage V_{START}, Schmidt trigger 222 provides a gate voltage to transistor 224 to switch that device off. With transistor 224 nonconductive, start-up circuit 218 does not interfere with the normal operation of the low-voltage supply independent bias circuit.

In operation AMP 216 may create a virtual input short where the voltage V1 equals the voltage V2. Further, without start-up circuit 218 the bias currents may be zero which is a stable but undesired second operating point and the voltages V1 and V2 have a zero potential. Without including Schmidt trigger 222 in supply independent bias circuit 200, both AMP 216 and AMP 220 could operate to regulate the voltage V_{CTL}. This would create a third stable state which is also undesirable when the loop gain from AMP 220 is greater than the loop gain from AMP 216, a condition that may happen if one or more transistors in AMP 216 enter the triode region at power-up. Thus, Schmidt trigger 222 is included in accordance with the present invention to prevent AMP 220 from regulating.

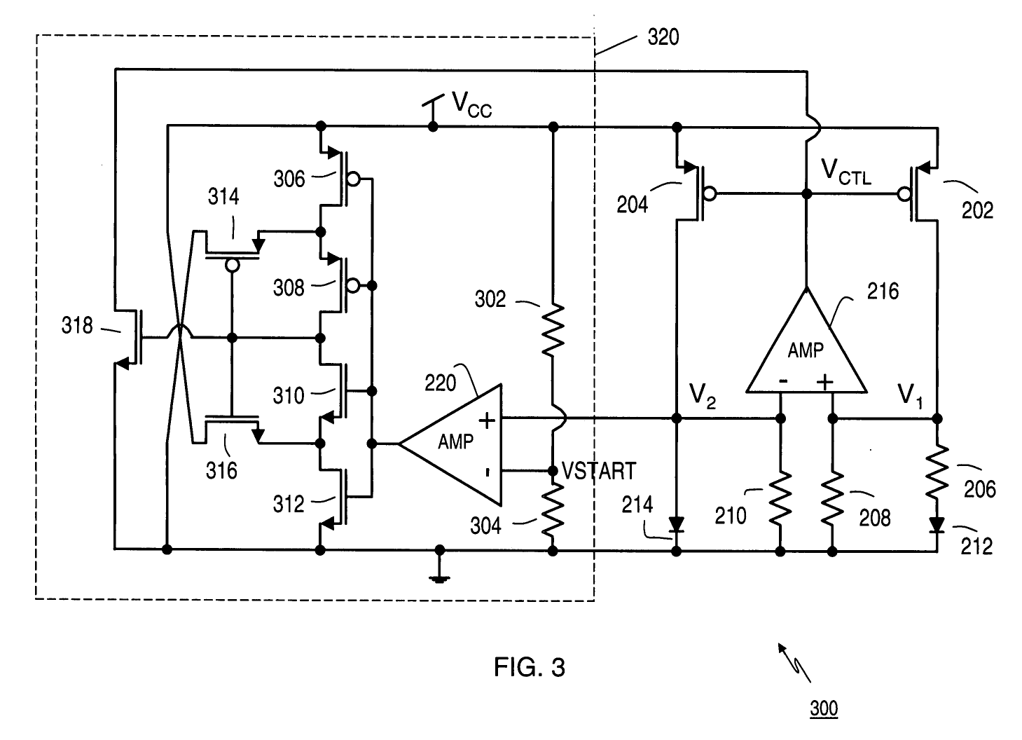

FIG. 3 shows a second simplified embodiment of a supply independent bias circuit 300 that includes a start-up circuit 320. The low-voltage supply independent bias circuit shown is again described by P-channel transistors 202 and 204, resistors 206, 208 and 210, diodes 212 and 214 and Operational Amplifier (AMP) 216. In this embodiment the voltage V_{START} may be set by a simple voltage divider of resistors 302 and 304. With the configuration shown in the figure, a range of voltage values for V_{START} is acceptable over variations of the V_{CC} operating voltage potential. In this embodiment the Schmidt trigger function is performed by P-channel transistors 306, 308 and 314 and N-channel transistors 310, 312 and 316. The voltage to trigger the high and low states may be designed by the proper sizing of the transistors 306-316.

In operation, the present invention implements a robust start-up circuit for supply independent bias circuits such as, for example, a bandgap reference circuit. Start-up circuit 320 performs well when operating from a single, low voltage supply close to 1 volt (V). Prior art implementations typically employ inverters or amplifiers that regulate to a second stable but undesired operating point rather than the desired operating point if the main feedback path (regulating op amp) enters a low-gain mode such as when one or more transistors enter the triode region. The Schmidt trigger formed by transistors 306-316 in the start-up path ensures that regulation to the undesired second state is avoided. Thus, hysteresis in the Schmidt trigger prevents the start-up from regulating to an undesired state and eliminates the zero current bias state.

As before, when the voltage V2 is lower than the voltage V_{START} supplied to one input of AMP 220, the Schmidt trigger switches to set the gate voltage of transistor 318 to a high voltage value. The high gate voltage forces current to flow through transistor 318, lowering the gate voltage of transistors 202 and 204. The current conducted by transistor 204 increases the node voltage V2, and when the voltage V2 is greater than the voltage V_{START}, the Schmidt trigger provides a gate voltage to transistor 318 to switch that device off. With transistor 318 nonconductive, start-up circuit 320 does not interfere with the normal operation of the low-voltage supply independent bias circuit. Thus, the Schmidt trigger switches to start the start-up circuit 320 when necessary then switches to disconnect when the circuit is in the desired operating state.

By now it should be apparent that embodiments of the present invention allow high-performance, supply independent bias circuits to start-up and operate while running from a small power supply voltage (approximately 1 Volt, for example). Whereas prior art start-up circuitry may fail with a low power supply voltage or when transistors of the control amplifier (typically, an op amp) enter the triode region, the present invention provides proper start up over process variations, temperature ranges, and supply voltage ramping, overshoot, and undershoot.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. A supply independent bias circuit, comprising:
a supply independent constant bias current circuit; and
a start-up circuit that includes a Schmidt trigger that avoids regulation to an undesired state of the supply independent constant bias current circuit.

2. The supply independent bias circuit of claim 1 wherein the supply independent constant bias current circuit is a bandgap current generator.

3. The supply independent bias circuit of claim 1 wherein the supply independent constant bias current circuit is a Proportional-To-Absolute-Temperature (PTAT) current generator.

4. The supply independent bias circuit of claim 1 wherein an input of the Schmidt trigger is set to a voltage potential by a voltage divider of resistors.

5. The supply independent bias circuit of claim 1 wherein the start-up circuit further includes an amplifier to provide an output to the Schmidt trigger and an N-channel transistor having a gate connected to an output of the Schmidt trigger, where the amplifier works with the Schmidt trigger to provide a desired start-up.

6. The supply independent bias circuit of claim 5 further including first and second transistors coupled between a power conductor and inputs of a second amplifier in the supply independent constant bias current circuit wherein a zero current conducted by the first and second transistors is the undesired state.

7. The supply independent bias circuit of claim 5 further including first and second transistors coupled between a power conductor and inputs of a second amplifier in the supply independent constant bias current circuit wherein a current greater than zero but less that desired design value is conducted by the first and second transistors.

8. A radio comprising:
a supply independent biasing that includes a bandgap current generator and a start-up circuit having a Schmidt trigger in a feedback path to regulate to a predetermined stable state of the supply independent biasing.

9. The radio of claim 8 wherein the start-up circuit further includes an amplifier having a first input coupled to the bandgap current generator and a second input to receive a voltage potential; an input of the Schmidt trigger coupled to an output of the amplifier; and an output transistor having a gate coupled to an output of the Schmidt trigger, wherein an output of the transistor provides a signal to the feedback path from the start-up circuit to the bandgap current generator.

10. The radio of claim 9 wherein the voltage potential supplied to the second input of the amplifier is a preset value that switches the start-up circuit to not interfere with normal operation of the bandgap current generator.

11. The radio of claim 8 wherein another input of the Schmidt trigger is set to a preset voltage potential by a voltage divider of resistors.

12. The radio of claim 9 wherein the start-up circuit provides the signal to the feedback path to avoid an undesired state.

13. A method to provide start-up for a supply independent constant bias current circuit comprising:
using a Proportional-To-Absolute-Temperature (PTAT) current generator in the supply independent constant bias current circuit; and
switching a start-up circuit coupled to the PTAT current generator that includes an amplifier and a Schmidt trigger to not interfere with normal operation of the PTAT current generator.

14. The method of claim 13 wherein the start-up circuit further includes regulating to avoid an undesired state.

15. The method of claim 13 further including supplying a preset voltage potential to an input of the amplifier to trigger the start-up circuit to switch.

16. The method of claim 15 wherein supplying a lower voltage potential by the PTAT current generator than the preset voltage potential causes the Schmidt trigger to switch to avoid interfering with the normal operation of the low-voltage supply independent bias circuit.
